(19) United States
(12) Patent Application Publication
(10) Pub. No.: US 2012/0068575 A1
(43) Pub. Date: Mar. 22, 2012

(54) Rotatable antifriction bearing

(76) Inventor: Max Abildgaard, Braunschweig (DE)

(21) Appl. No.: 13/232,352

(22) Filed: Sep. 14, 2011

(30) Foreign Application Priority Data
Sep. 21, 2010 (DE) 10 2010 045 912.7
Feb. 8, 2011 (DE) 20 2011 002 485.7

(51) Int. Cl. H01L 41/113; H01L 41/04

(52) U.S. Cl. 310/319; 310/338

(57) ABSTRACT

The invention relates to a rotatable antifriction bearing (1) having a first bearing ring (2), a second bearing ring (3) which can be rotated with respect to the first bearing ring (2), and a plurality of rolling bodies (4) which are arranged between the first and the second bearing ring (2, 3), at least one rolling body (4) being configured as an electric sensor in such a way that the rolling body (4) is set up for changing a directly electrically detectable characteristic variable as a function of a force which is exerted on said rolling body (4). Moreover, the invention relates to a rolling body for an antifriction bearing of this type, and to a device having an antifriction bearing and an electric monitoring device.

The invention relates to a rotatable antifriction bearing according to the preamble of claim 1. Moreover, the invention relates to a rolling body for an antifriction bearing of this type according to claim 20 and to a device having an antifriction bearing and an electric monitoring device according to claim 21.

In general, the invention relates to the field of the monitoring of antifriction bearings during their operation. In this context, antifriction bearings are to be understood as all types of bearings, in which two components which can move relative to one another, namely a first bearing ring and a second bearing ring, are separated from one another by rolling bodies. This includes, in particular, ball bearings, roller bearings and needle bearings of any design, in particular as radial bearings or axial bearings. Accordingly, the rolling body can be, for example, a ball, a cylindrical roller, tapered roller or spherical roller or, in the case of a needle bearing, a needle bush.

Antifriction bearings are used everywhere in engineering. They have a long service life and can be used simply, but can also develop defects which can lead to high repair costs. Typical defects are what is known as pitting, in which small pressure marks and/or chips are formed in the rolling body raceways. Pitting of this type is usually produced slowly and can be detected. An operator of a machine, in which an antifriction bearing of this type is operated, is frequently interested in a forecast of when a repair and/or a replacement of the antifriction bearing is required. For this purpose, measurements of structure borne sound have typically been carried out up to now. Here, an acceleration sensor which acts similarly to a microphone is used to detect the vibrations of the antifriction bearing. As a result, in particular, the characteristic noises which are caused by the rolling bodies when they roll over the pitting can be recorded. However, an analysis of this type of structure borne sound is relatively complicated and expensive and cannot always locate a defective antifriction bearing accurately.

The invention is therefore based on the object of specifying a rotatable antifriction bearing which affords improved diagnosis options and of specifying a rolling body for said antifriction bearing. Furthermore, a possibility for monitoring an antifriction bearing of this type is to be specified.

This object is achieved by the invention which is specified in claims 1, 20 and 21. The dependent claims specify advantageous refinements of the invention.

According to the invention, a completely different principle is proposed than the signal detection previously used for the diagnosis of antifriction bearings by way of sensors which are arranged on the outside of the antifriction bearing or its surroundings. According to the invention, at least one rolling body of the antifriction bearing is configured itself as an electric sensor, to be precise in such a way that a directly electrically detectable characteristic variable can be varied by this rolling body, to be precise as a function of a force which is exerted on said rolling body. The rolling body itself is therefore made pressure sensitive. The rolling body is therefore configured as a component which can be varied with regard to an electric characteristic variable. By way of this, a detection of the electrically detectable characteristic variable can advantageously take place both at a standstill of the antifriction bearing and when the antifriction bearing is rotating. A connection of the rolling body which is configured as an electric sensor to electric lines for detecting the characteristic variable is namely not required. Rather, in the case of an electrically conductive configuration of the first bearing ring and of the second bearing ring, the detection of the characteristic variable can take place directly on said components, for example via a firmly attached electric contact on the stationary bearing ring and a rubbing contact on the rotating bearing ring. As a result of the rolling body which is configured as an electric sensor, a characteristic variable of the rolling body is therefore variable as a function of the force or the pressure which is exerted on the rolling body. As a result, a characteristic variable of the antifriction bearing is also variable as a function of the force or the pressure which is exerted on the rolling body.

It is a further advantage of the invention that a completely continuous detection of the bearing state over the entire circumference of the antifriction bearing becomes possible by way of the invention. The reason for this is that the rolling bodies themselves act as sensors. Since the rolling bodies roll continuously over the entire bearing circumference during operation of the antifriction bearing, each point of the circumference can be detected. In this way, an even spatially more precise detection of effects is possible by way of the invention, in comparison with, for example, discretely distributed sensors.

The invention has the further advantage that a directly electrically detectable characteristic variable can be varied. A directly electrically detectable characteristic variable is understood to be every characteristic variable which can be detected directly by way of electric means without conversion into another physical variable, for example light or movement. This allows a detection of the characteristic variable with only low outlay, in particular without special sensors which convert from one physical variable into another physical variable, such as mechanical movements into an electric signal. In principle every electric variable which can be detected directly by electric sensors comes into consideration as directly electrically detectable characteristic variable, such as voltage, current, resistance, capacitance or inductance of the antifriction bearing and/or of the rolling body.

The invention has the further advantage that the electrically detectable characteristic variable which can be recorded from the rotatable antifriction bearing can be evaluated by way of existing evaluation systems. Merely an electric adaptation to the signal type is required.

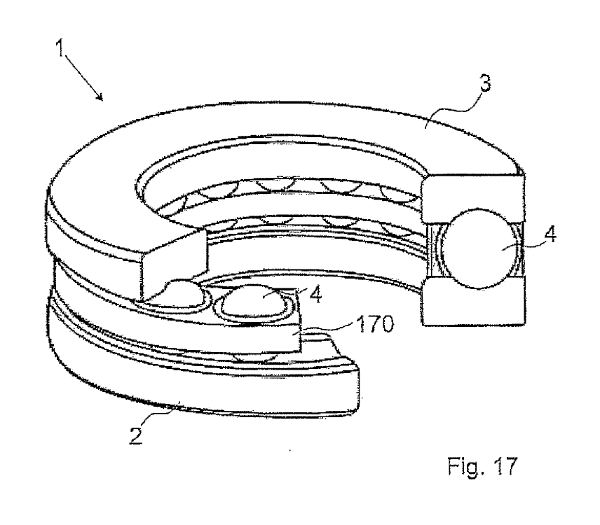

The invention is suitable both for radial bearings, axial bearings or modifications thereof. In the case of a radial bearing, the first bearing ring according to the claim is, for example, the inner bearing ring, and the second bearing ring is then the outer bearing ring. In the case of an axial bearing, the first bearing ring according to the claim is, for example, the lower bearing ring depicted in FIG. 17, and the second bearing ring is then the upper bearing ring.

According to one advantageous development, the rolling body which is configured as an electric sensor is configured as a piezoelectric sensor or as a piezoresistive sensor. In the case of a configuration as a piezoelectric sensor, the sensor outputs a voltage or a current as electric characteristic variable as a function of the pressure. In the case of a configuration as a piezoresistive sensor, the rolling body has a variable electric resistance which is a function of the force which is acting. Both alternatives permit inexpensive industrial large series production of rolling bodies of this type and of antifriction bearings equipped with the latter, and simple and accurate signal detection.

According to one advantageous development of the invention, the rolling body which is configured as an electric sensor is produced from a piezoresistive material or has a coating which is made from a piezoresistive material and is applied to an inner core of the rolling body. Piezoresistive materials have the advantage that they are available inexpensively and can be processed satisfactorily. The second alternative, in which a coating made from the piezoresistive material is applied to an inner core of the rolling body, has the advantage that the piezoresistive material can be used more sparingly and less expensive production is therefore possible. Here, the core of the rolling body can consist of a customary material for rolling bodies, such as steel or ceramic. In particular, a relatively hard core is advantageous in order to ensure longlasting functioning of the antifriction bearing. The coating made from the piezoresistive material can advantageously be applied to the rolling body as a thin layer. This has the advantage that conventional rolling bodies, for example balls or tapered rollers, can be used in a practically unchanged form as starting component, can be provided with the coating and can be installed in an antifriction bearing of an existing design, which antifriction bearing is likewise otherwise unchanged with regard to its geometry. The coating advantageously has a thickness of approximately 6 μm.

According to one advantageous development of the invention, the coating made from the piezoresistive material is produced with doped or undoped hydrocarbon or pure carbon. According to one advantageous development of the invention, at least one wear protection layer is applied to said piezoresistive sensor layer. The wear protection layer is advantageously of electrically conductive configuration. If the rolling body is produced from the piezoresistive material, the wear protection layer can be applied to the rolling body. For example, a doped hydrocarbon or diamond-like carbon can be used as material for the wear protection layer.

According to one advantageous development of the invention, the coating is applied homogeneously to the rolling body. The coating advantageously has approximately the same layer thickness everywhere. According to one advantageous development of the invention, the coating covers the entire rolling body or at least those faces of the rolling body which absorb the load during rolling. Thus, for example, it is sufficient in the case of a cylindrical roller bearing or a tapered roller bearing to provide only the running faces of the rolling bodies with the coating. In the case of a ball bearing, it is advantageous to provide the balls with the coating on the entire outer face.

According to one advantageous development of the invention, the wear protection layer has a plurality of conductive zones which are insulated with respect to one another or are at least highly resistive in comparison with the rolling bodies. It has been determined that it is important that the wear protection layer has the correct electric properties: firstly it has to be satisfactorily conductive enough that there is an electric connection, and secondly it has to be poorly conductive enough that the current does not simply run through it without passing the piezoresistive sensor layer. Moreover, the wear protection layer has to be wear resistant. This optimization problem can be solved by the wear protection layer being of inhomogeneous design, for example by virtue of the fact that it is divided into many small regions which have a poor conductivity with respect to one another. The wear protection layer can also be formed, for example, in small zones which are delimited from one another. The current is therefore forced to run into the piezoresistive sensor layer.

According to one advantageous development of the invention, the second bearing ring is insulated with respect to the first bearing ring or is at least highly resistive in comparison with the rolling bodies. This has the advantage that an electric current flow takes place only in a defined way via the rolling body which is configured as an electric sensor and no direct current flow can take place from the second bearing ring to the first bearing ring. As a result, the detection accuracy of the electrically detectable characteristic variable can be improved. The transfer resistance from the second bearing ring to the first bearing ring advantageously has a value which is at least ten times as great as the resistance which is formed via the rolling bodies in the case where there is no pressure loading.

The invention comprises the possibility that a single rolling body is configured as an electric sensor, or that a plurality of the rolling bodies are configured as electric sensors or all the rolling bodies are configured as electric sensors. In every case, a detection of defects on the antifriction bearing is possible. According to advantageous developments of the invention, a deliberate asymmetry is provided with regard to the rolling bodies which are configured as electric sensors, which asymmetry has the advantage that, in addition to the pure detection of a defect, a determination of the position of the defect with regard to the circumference of the antifriction bearing is possible.

According to one advantageous development of the invention, a plurality of rolling bodies are configured as electric sensors. The spacings of said rolling bodies from one another in the circumferential direction of the antifriction bearing are unequal. As a result, the rolling bodies which are configured as electric sensors are arranged distributed asymmetrically over the circumference of the antifriction bearing. Here, not all rolling bodies are configured as electric sensors.

According to one advantageous development of the invention, a plurality or all of the rolling bodies are configured as electric sensors. Here, a part quantity of said rolling bodies has a different electric characteristic than the remaining rolling bodies which are configured as electric sensors. Thus, for example, a first part quantity of the rolling bodies can have a first electric characteristic (first resistance) and a second part quantity of the rolling bodies can have a second, electric characteristic (second resistance) which differs from the first electric characteristic. More than two part quantities or groups of rolling bodies with different electric characteristics can also be provided.

According to one advantageous development of the invention, the rolling bodies which are configured with the same electric characteristic are arranged such that they are distributed asymmetrically over the circumference of the antifriction bearing.

According to one advantageous development of the invention, the first bearing ring and/or the second bearing ring have/has at least one inhomogeneity, in particular at least one defined conductivity modification, with regard to the directly electrically detectable characteristic variable in the region of the rolling surface of the rolling bodies. As a result, a defined reference position can likewise be produced which forms a reference for the position of the rolling bodies. By means of the inhomogeneity, a determination of the position of the defect with regard to the circumference of the antifriction bearing is possible using the detected characteristic variable.

The invention is suitable both for antifriction bearings with a rolling body cage and for antifriction bearings without a rolling body cage. According to one advantageous development of the invention, the antifriction bearing has a rolling body cage which is provided for spacing the rolling bodies from one another. Here, the rolling body cage is produced from an insulating material or is coated with the latter. As a result, the detection accuracy of the electrically detectable characteristic variable can likewise be improved. In particular, undesirable influences as a result of stray currents between rolling bodies are avoided. The rolling body cage can be produced, for example, from ceramic or a plastic, for example Teflon or nylon. Customary rolling body cages are already composed partly of fiber reinforced plastic.

According to one advantageous development of the invention, the rolling body is produced from or using pressure sensitive particles which themselves change a directly electrically detectable characteristic variable as a function of a force which is exerted on them. It is advantageous, in particular, to produce the rolling body exclusively from the pressure sensitive particles, it optionally being possible for a proportion of binding agent to be provided. According to a further advantageous development of the invention, the rolling body is produced from a mixture of the pressure sensitive particles and of metal particles. Here too, a binding agent can be provided additionally. Here, the rolling body can be produced, in particular, by a sintering process. The metal particles can consist, for example, of a sintered metal. Here, a rolling body can be produced, in which the current also flows significantly through the pressure sensitive material.

One advantageous production method for a rolling body of the above-described type can be configured as follows:
a) provision of a starting material in the form of small particles, for example pulverulent, the starting material having at least the pressure sensitive particles, optionally additionally metal particles and optionally additionally a binding agent,
b) pressing of the starting material into the desired shape of the rolling body,
c) heating of the blank produced according to step b) with simultaneous exertion of pressure onto the blank.

In step c), heating can advantageously take place to, for example, from 60 to 70% of the melting point of the pressure sensitive particles or of the metal particles. If they have different melting points, the lower melting point is to be used. As a result, a rolling body is produced by means of a sintering process. The product which is produced here has a strong bond between the particles and a great hardness which is sufficient for antifriction bearings. Optionally, the rolling body which is produced is also to be brought into a final shape by a subsequent grinding or polishing process. As a result, a pressure sensitive rolling body is produced which changes a directly electrically detectable characteristic variable as a function of a force which is exerted on the rolling body. In particular, piezoresistive materials can be used as pressure sensitive particles, for example the above-described piezoresistive materials of the coating. As a result, a rolling body is produced which changes its electric conductivity or the electric resistance as a function of the pressure which is exerted on it.

According to one further development of the invention, the rolling body is produced from or using metal particles which have a coating which is applied to an inner metal core and is made from a piezoelectric or piezoresistive material. For example, metal particles of spherical shape can be used, with the result that the rolling body is produced from a multiplicity of small metal balls with a respectively pressure sensitive coating, which then themselves represent pressure sensitive particles. The production of the rolling body can likewise take place according to the above-described method.

According to one advantageous development of the invention, in the region of the rolling surface of the rolling bodies, the first bearing ring and/or the second bearing ring of the antifriction bearing have/has at least two electric contact faces which are arranged distributed over the circumference of the rolling surface, are insulated with respect to one another and are made from electrically conductive material for making contact with the rolling bodies. As a result, the rolling surface of the rolling bodies which is also called the raceway can be provided with two or more individual contact segments which are distributed over the circumference of the antifriction bearing and can be used in each case for making electric contact with the rolling bodies. Here, the electric contact faces which are insulated with respect to one another can be connected via electric conductor tracks to a monitoring device or evaluation device for detecting electric characteristic variables of the antifriction bearing. Thus it is possible, for example, to provide the rolling surface over the circumference with two electric contact faces which are insulated with respect to one another and in each case wrap around approximately 180 degrees, for example on the second bearing ring. This permits a detection of the directly electrically detectable characteristic variable of the antifriction bearing by making electric contact with only one bearing ring, the second bearing ring in the stated example. As an alternative, the first bearing ring can also be used. That bearing ring is advantageously provided with the electric contact faces which are insulated with respect to one another, which bearing ring does not rotate in the concrete application of the antifriction bearing. In this way, a robust and reliable electric contact can be realized without rubbing contacts and therefore without appreciable transfer resistances.

The rolling surface can likewise be provided with more than two contact faces which are insulated electrically with respect to one another, for example with a multiplicity of relatively small segments which are in each case connected separately via electric lines to an evaluation or monitoring device. As a result, locations of particularly high or particularly low loadings can be detected on the antifriction bearing and can be localized more precisely with regard to their position on the circumference of the antifriction bearing.

According to one advantageous development of the invention, in the region of the rolling surface of the rolling bodies, the first bearing ring and/or the second bearing ring of the antifriction bearing have/has electric contact faces which are arranged distributed in the direction of the rotational axis of the antifriction bearing, are insulated with respect to one another and are made from electrically conductive material for making contact with the rolling bodies. In an analogous manner to the above-described arrangement of electric contact faces which are distributed over the circumference of the rolling surface and are insulated with respect to one another, an arrangement is therefore proposed of electric contact faces which are arranged distributed in the transverse direction thereto, that is to say in the direction of the rotational axis of the antifriction bearing, and are insulated with respect to one another. They can likewise be connected separately via electric lines to an evaluation or monitoring device. A combination of electric contact faces which are arranged distributed over the circumference of the rolling surface and in the direction of the rotational axis of the antifriction bearing and are insulated with respect to one another is also advantageous. This allows the detection of further data which are relevant during operation of an antifriction bearing, such as transversely acting loads and bending moments.

The electric contact faces can be applied, for example as a metal layer, to a rolling surface which is insulated on the surface, for example by vapor deposition. The rolling surface can be insulated, for example, by applying an insulation layer to a first or second bearing ring. The entire first or second bearing ring can advantageously also be produced from an insulating material, for example from ceramic or from plastic.

Furthermore, the invention relates to a rolling body for an antifriction bearing of the above-described type. The rolling body can be provided, for example, as an accessory part or replacement part for an antifriction bearing of this type.

Furthermore, the invention relates to a device having an antifriction bearing of the above-described type and an electric monitoring device. The monitoring device is connected electrically to the antifriction bearing. The monitoring device is set up for detecting the directly electrically detectable characteristic variable of the rolling bodies or the antifriction bearing.

To this end, the monitoring device can be connected to two or more of the above-described electric contact faces of the first or second bearing ring which are insulated with respect to one another. It is likewise advantageous to connect the monitoring device electrically to the second bearing ring and the first bearing ring of the antifriction bearing. The monitoring device is then set up for detecting an electric characteristic variable between the second bearing ring and the first bearing ring.

In this way, permanent monitoring of the antifriction bearing and detection of defects can be realized by way of simple and inexpensive means. During detection of the resistance, the antifriction bearing can be loaded, for example, with a DC voltage or an AC voltage. For the detection, a defined voltage can be applied and the resulting current can be measured, or a defined current can be applied and the resulting voltage can be measured. It is also possible to measure current and voltage if there is no constant current or voltage source.

During detection of the capacitance or the inductance, an alternating signal, for example a pulsed signal or an alternating voltage, is advantageously applied to the antifriction bearing. The amplitude and/or the phase relation of the alternating signal can be detected, for example.

According to one advantageous development of the invention, the monitoring device is set up for evaluating the time profile of the detected electric variable for irregularities. If an irregularity which exceeds a predefined dimension is determined, the monitoring device outputs a warning signal. As a rule, the monitoring of the time profile has to take place over a relatively long time period, since typical antifriction bearing faults are produced in a slow process which becomes visible only by observation of the detected electric characteristic variable over a relatively long time period. Thus, for example, a frequency diagram can be produced for evaluation. Using the frequency diagram, it can be determined by an observation over a relatively long time period, for example over several months, that the signal amplitude increases slowly at a defined frequency or a frequency range.

According to one advantageous development of the invention, the monitoring device is set up for defining slip states and/or states of increased loading or wear of the antifriction bearing from the detected electric characteristic variable and for generating an output signal which characterizes states of this type. There is a slip state if the first bearing ring rotates with respect to the second bearing ring, but the rolling bodies do not roll at the corresponding rotational speed, but rather are pushed along at a standstill or rotating slowly. As a result, slip is produced between the rolling bodies and the first and/or the second bearing ring. Slip states of this type occur mainly in the case of antifriction bearings which are running in an unloaded state. For this purpose, it can be provided, for example, that the monitoring device monitors the detected electric characteristic variable with respect to the antifriction bearing being substantially unloaded. This is determined by the fact that the directly electrically detectable characteristic variable has a value over a predefined time period, which value corresponds to a force which lies below a predefined, lower threshold and acts on the antifriction bearing. In the case of the measurement of the ohmic resistance of the antifriction bearing as characteristic variable, it can be monitored, for example, on the basis of the reciprocal relationship between the ohmic resistance and the force which acts on the antifriction bearing whether the measured ohmic resistance lies above a predefined threshold over a predefined time period. A state of increased loading or wear of the antifriction bearing can then be determined if, after a phase of this type of unloaded operation of the antifriction bearing, the force which acts on the antifriction bearing rises, that is to say the ohmic resistance drops. This namely leads to the rolling bodies changing suddenly from a stationary or slowly rotating state which is set on account of the bearing play in the case of an antifriction bearing which is rotating in an unloaded state into a rapidly rotating state. This leads over time to wear and to defects on the antifriction bearing. The proposed output signal which characterizes states of this type can indicate cases of this type. For example, a display device, for example a warning lamp, can be actuated via the output signal. A further possible application comprises temporally summing the states of increased loading or wear of the antifriction bearing, for example by temporal integral formation of the output signal, and of producing an indication therefrom for a maintenance or repair requirement for the antifriction bearing.

According to one advantageous development of the invention, the abovementioned output signal can be used as control signal, in order to counteract states of increased loading or wear of the antifriction bearing. According to one advantageous development of the invention, a control device is provided which is set up for receiving the control signal and, in the case of a slipstate being determined and/or if increased loading or wear of the antifriction bearing is determined, for reducing or for avoiding loading or wear of the antifriction bearing which is current or is imminent as a result of the slip state. If current loading or wear is counteracted, this can take place immediately. In the case of loading or wear of the antifriction bearing which is imminent as a result of the slip state, it is advantageous, after the slip state is determined, to monitor when the antifriction bearing is to be loaded again and the rolling bodies therefore leave the slip state and suddenly start to run again. If this state is determined, a gentle method can be used, for example, such as a reduction in the rotational speed of the antifriction bearing, before the antifriction bearing is subjected to loading. According to one advantageous development of the invention, this can take place by virtue of the fact that the control device is set up for at least temporarily reducing and/or only slowly increasing the rotational speed which acts on the antifriction bearing. It can likewise be provided to increase a detected loading of the antifriction bearing only slowly. These measures have a conserving effect on the antifriction bearing, with the result that the service life of the antifriction bearing is increased. Here, in particular, a predefined time gradient for the slow increase can be fixed.

According to one advantageous development of the invention, the monitoring device is set up for using the detected electric characteristic variable to locally define an actual loading maximum and/or loading minimum of the antifriction bearing along the rolling surface of the rolling bodies over the circumference of the antifriction bearing and/or in the direction of the rotational axis of the antifriction bearing. This can take place, for example, by evaluation of electric signals at different electric contact faces which are arranged in the rolling surface. As a result of the defining and spatial localization of a loading maximum and/or a loading minimum, improved predictions can be made about possible faulty loadings of the antifriction bearing and future defects. In particular, it becomes possible to determine the causes of faulty loadings of this type at an early stage and to counteract them.

According to one advantageous development of the invention, the monitoring device is set up for using the detected electric characteristic variable to define a radial force, an axial force and/or a bending moment which acts on the antifriction bearing and/or the direction of action of the bending moment. Said variables are defined indirectly, by a spatial pressure distribution of the rolling bodies on the bearing rings being calculated first of all and the above-mentioned variables being defined therefrom. An axial force is understood to be a force component which acts on the antifriction bearing in the longitudinal direction of the rotational axis of the antifriction bearing. A bending moment is understood to be a loading of the type which, on account of an external action of force, leads to flexural loading, for example, on a shaft which passes through the antifriction bearing. Said bending moment attempts to change the rotational axis of the antifriction bearing. A radial force is understood to be a force component which is exerted on the antifriction bearing directly or on the antifriction bearing via a component which is connected to the antifriction bearing, in the radial direction, that is to say perpendicularly with respect to the rotational axis of the antifriction bearing.

According to one advantageous development of the invention, the monitoring device is connected electrically only to the second bearing ring or only to the first bearing ring of the antifriction bearing. The monitoring device is set up for detecting an electric characteristic variable between at least two contact faces of the second bearing ring or of the first bearing ring, which contact faces are insulated electrically with respect to one another. According to one advantageous development of the invention, the at least two contact faces which are insulated electrically with respect to one another are arranged in the rolling surface of the rolling bodies in the first bearing ring or the second bearing ring. According to one advantageous development of the invention, that bearing ring, to which the monitoring device is connected electrically, is configured as a static bearing ring which does not rotate during the operation of the antifriction bearing.

Furthermore, the invention relates to advantageous methods for monitoring the directly electrically detectable characteristic variable of a rotatable antifriction bearing of the above-described type. According to a first embodiment, the time profile of the detected electric characteristic variables is evaluated for irregularities in one method and, if an irregularity which exceeds a predefined dimension is determined, a warning signal is output.

In a further embodiment of the method, the detected electric characteristic variable is used to define states of increased loading or wear of the antifriction bearing and to generate an output signal which characterizes states of this type.

In a further embodiment of the method, the output signal which characterizes states of this type is used as control signal, in order to reduce or to avoid the loading or wear of the antifriction bearing by means of a control device if increased loading or wear of the antifriction bearing is determined. In a further embodiment of the method, it is provided, in order to avoid or reduce the increased loading or wear, to at least temporarily reduce and/or to only slowly increase the rotational speed which acts on the antifriction bearing and/or to increase a detected loading of the antifriction bearing only slowly.

In a further embodiment of the method, the detected electric characteristic variable is used to locally define an actual loading maximum and/or a loading minimum of the antifriction bearing along the rolling surface of the rolling bodies over the circumference of the antifriction bearing and/or in the direction of the longitudinal axis of the antifriction bearing.

In a further embodiment of the method, the electric characteristic variable is used to define a radial force, an axial force and/or a bending moment which acts on the antifriction bearing and/or the direction of action of the bending moment.

In the following text, the invention will be explained in greater detail using exemplary embodiments with the use of drawings, in which:

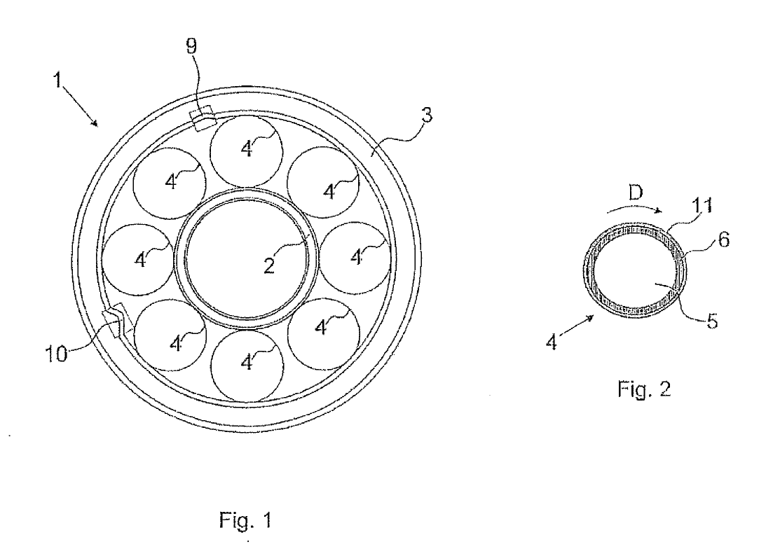

FIG. 1 shows an antifriction bearing, and

FIG. 2 shows a rolling body, and

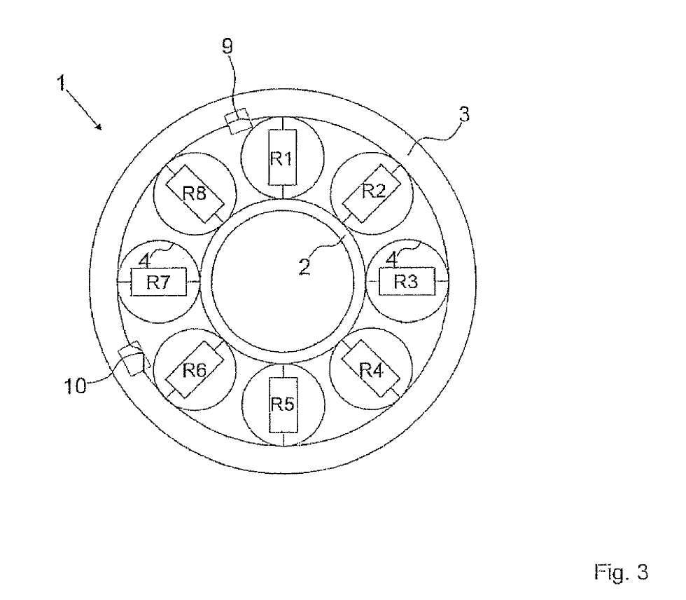

FIG. 3 shows an electric representation of the antifriction bearing, and

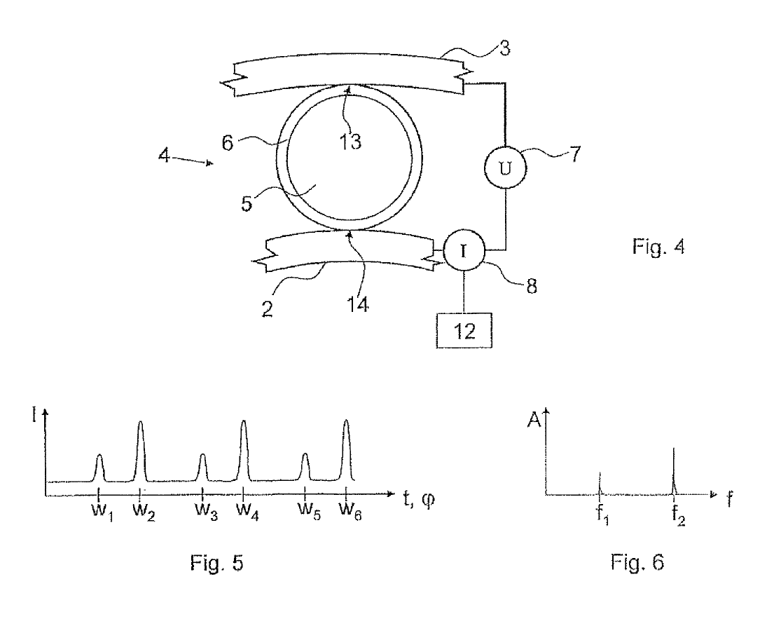

FIG. 4 shows an antifriction bearing with a monitoring device, and

FIG. 5 shows the profile of a characteristic variable in a time diagram, and

FIG. 6 shows the profile of a characteristic variable in a frequency diagram, and

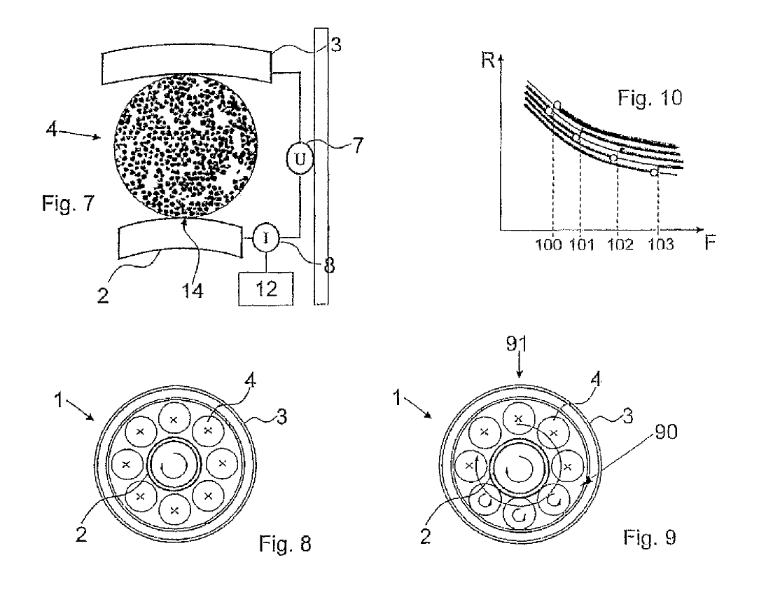

FIG. 7 shows a further embodiment of an antifriction bearing with a monitoring device, and

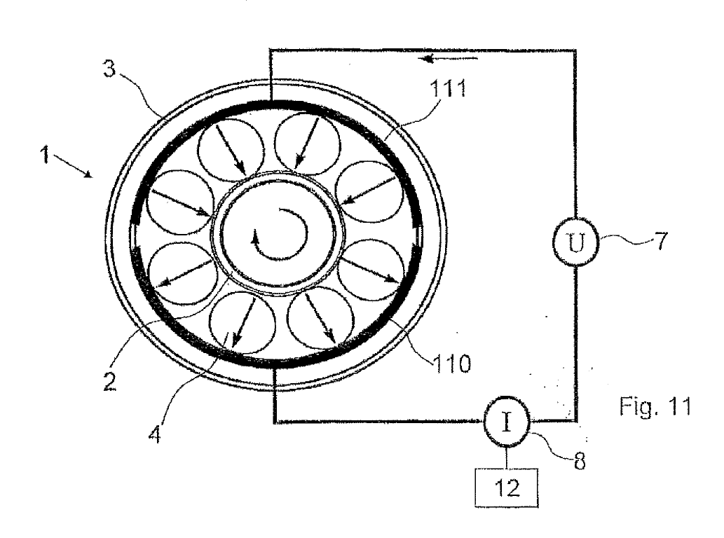

FIGS. 8 and 9 show an antifriction bearing with bearing play, and

FIG. 10 shows a resistance/force characteristic curve of an antifriction bearing, and

FIG. 11 shows a further embodiment of an antifriction bearing with a monitoring device, and

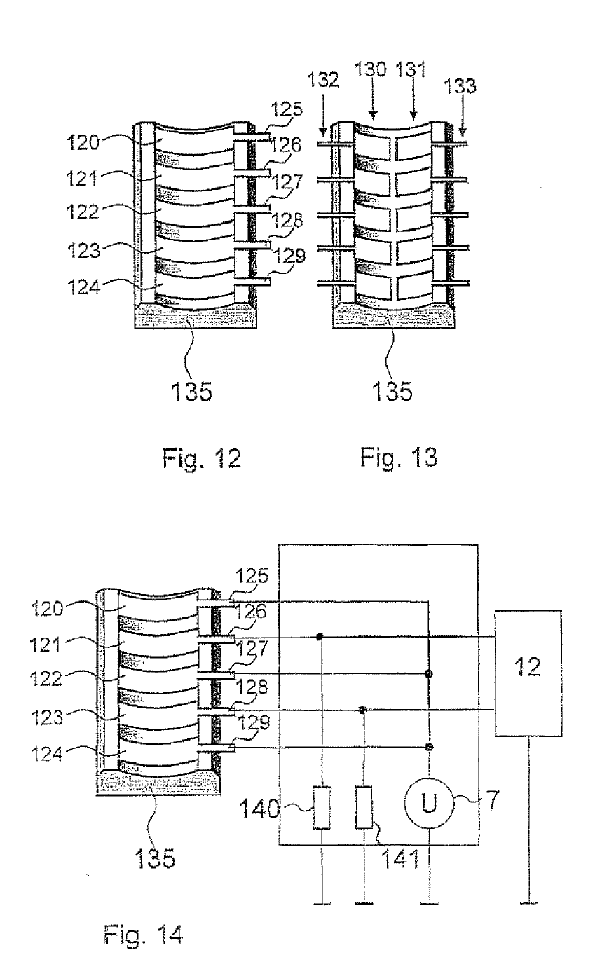

FIGS. 12 and 13 show a partial illustration of the rolling surface of the rolling bodies in an antifriction bearing, and

FIG. 14 shows a further embodiment of an antifriction bearing with a monitoring device, and

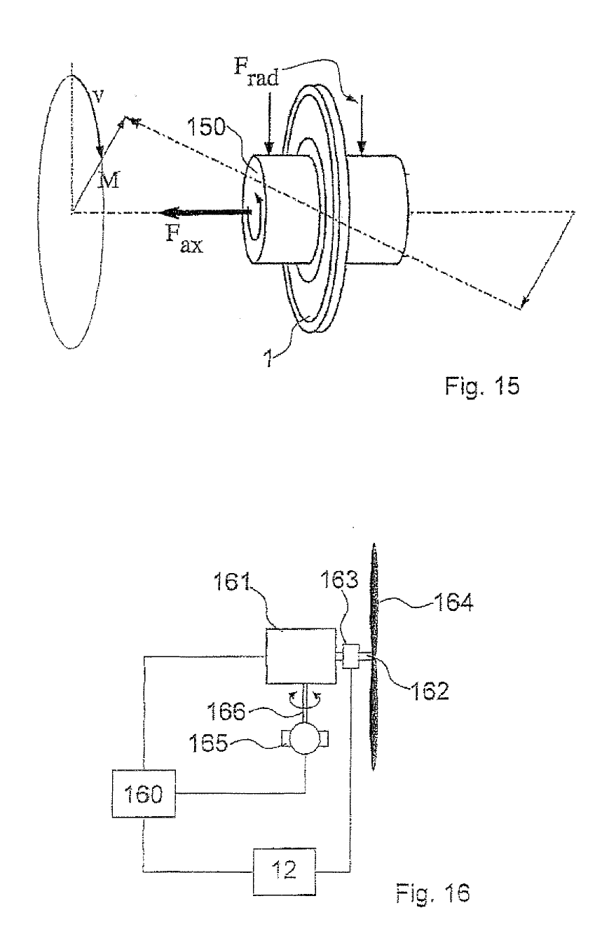

FIG. 15 shows an illustration of the forces and moments which act on an antifriction bearing, and

FIG. 16 shows an application of an antifriction bearing in a wind power plant, and

FIG. 17 shows a further antifriction bearing.

In the figures, identical reference numerals are used for elements which correspond to one another.

FIG. 1 shows an antifriction bearing 1 in the form of a radial bearing, having a first bearing ring 2 which is configured as an inner bearing ring, a second bearing ring 3 which is configured as an outer bearing ring, and a plurality of rolling bodies 4 which are arranged between the inner bearing ring 2 and the outer bearing ring 3. A number of eight rolling bodies is shown by way of example. The outer bearing ring 3 can be rotated with respect to the inner bearing ring 2. In the case of a rotation of the outer bearing ring 3 with respect to the inner bearing ring 2, the rolling bodies 4 are set in rotation and roll over the inner bearing ring 2 and the outer bearing ring 3.

By way of example, FIG. 1 also shows two defects 9, in the form of pitting on the outer bearing ring 3. In order to be recognized more clearly, the defects 9, are shown on an exaggeratedly large scale; in reality, defects of this type are substantially smaller and are frequently difficult to detect with the naked eye.

FIG. 2 shows, by way of example, a rolling body 4 which has a core 5 made from hard material, for example steel or ceramic. A piezoresistive coating 6 is applied to the core 5. A wear protection layer 11 is applied to the piezoresistive coating 6. FIG. 2 shows the coating 6 and the wear protection layer 11 in a sectional illustration. The coating 6 and the wear protection layer 11 cover at least the regions of the rolling body 4 which can come into contact with the inner bearing ring 2 and the outer bearing ring 3 during operation of the antifriction bearing 1. For the sake of clarity, the thickness of the two layers 6, 11 is shown on a substantially enlarged scale.

By way of example, the rotational direction of the rolling body 4 is shown by an arrow D.

FIG. 3 shows the antifriction bearing 1 according to FIG. 1 in a diagrammatic illustration, the rolling bodies 4 being characterized with regard to their electric properties by an electric component, a resistance here by way of example. The resistances of the eight rolling bodies 4 are denoted as R1 to R8. It is to be assumed by way of example that all the rolling bodies 4 are provided with the piezoresistive coating 6 and optionally the wear protection layer 11. Here, furthermore, it is to be assumed that seven of the rolling bodies 4 are provided with the piezoresistive coating in such a way that they in each case have the same resistance R in the state in which they are not loaded by pressure. With regard to the rolling body R8, it is to be assumed that it is coated in such a way that a different resistance, for example 2R, results in the state in which it is not loaded by pressure. In general terms, the rolling body R8 is coated in such a way that there is a different relationship between pressure and resistance than in the remaining rolling bodies. As a result, the resistance R8 forms a reference variable, to which reference can be made in the case of an evaluation of the signals of the sensors with regard to the other rolling body.

As can be seen, each rolling body 4 is embedded between the outer and the inner bearing rings, as is customary in antifriction bearings. The outer and the inner bearing rings are satisfactorily electrically conductive. At the points at which the rolling bodies rest on the bearing rings, there is a mechanical and electric contact between the rolling body and the respective bearing ring. As a result of the embedding, a mechanical force prevails at the contact points of the rolling body with the outer and inner bearing rings. The mechanical force acts locally on the force sensitive and/or pressure sensitive piezoresistive coating of the rolling body. As a consequence of this force and/or this pressure, the resistance changes locally in the coating in the region of the pressure point and from the pressure point to the rolling body core 5. The rolling body core 5 is satisfactorily electrically conductive, with the result that there is a low-resistance connection from the underside of the coating of a pressure point to the underside of the coating of the pressure point on the other side of the rolling body. As a result, the rolling body is configured as a sensor, in which the resistance changes from one pressure point to the other pressure point as a function of the mechanical loading of the rolling body.

It is also possible to use a nonconductive rolling body core 5. The electric connection is then formed exclusively by conduction in the pressure sensitive layer 6.

If a rolling body then rolls over a defect 9, 10, the mechanical loading changes, that is to say the pressure on the rolling body rises. As a result, the resistance value of the rolling body also changes, and therefore the resistance value between the inner bearing ring 2 and the outer bearing ring 3 also changes. This variation in resistance can be measured as a directly electrically detectable characteristic variable.

FIG. 4 shows a section through the antifriction bearing 1 in the circumferential direction, that is to say in the running direction of the rolling body 4 which is configured as a ball. As can be seen, the ball 4 is clamped in between the outer bearing ring 3 and the inner bearing ring 2. This results in a pressure point 13 between the outer bearing ring 3 and the ball 4 and a pressure point 14 between the inner bearing ring 2 and the ball 4. According to FIG. 4, an electric monitoring device 7, 8, 12 is connected to the antifriction bearing. The electric monitoring device has a voltage source 7. One pole of the voltage source is connected to the outer bearing ring 3 via an electric line, and the other pole is connected to the inner bearing ring 2 via an electric line and a current sensor 8 which is arranged in said electric line. The current sensor 8 can be configured, for example, as an instrument shunt. The current sensor 8 is connected to an electronic detection and evaluation device 12, for example an oscilloscope, a transient recorder or another digital signal processing device.

As already mentioned, a current source can also be used and the voltage can be detected instead.

By way of example, FIG. 5 shows a current signal which is recorded by the evaluation device 12 and is shown against time t. The illustration according to FIG. 5 can advantageously also be an illustration of the current signal I against an angular coordinate φ which runs in the circumferential direction of the antifriction bearing. In order to illustrate the current signal I, the evaluation device 12 can be configured in both alternatives. The evaluation device 12 advantageously defines the current signal I against the angular coordinate p with consideration of a rotational speed signal or an angular signal which is fed to the evaluation device 12. Simple detection of the position of the defect 9, 10 is permitted, in particular, in the illustration of the current signal against the angular coordinate p.

In order to simplify the illustration, it is to be assumed for the current signal I according to FIG. 5 that the antifriction bearing has only one defect, to be precise the defect 9. When rolling over the defect 10 or defect 9, the balls 4 are clamped either to a greater or a lesser extent. As a result, the pressure changes at the contact points between balls and bearing rings. The resistance of a ball therefore changes when it rolls over a defect. Furthermore, it is to be assumed that only the rolling bodies with the resistance values R1 and R6 are configured as electric sensors, and the remaining rolling bodies are electrically neutral, that is to say are insulated in this case. Furthermore, it is to be assumed that R1 has the value R, and R6 has the value 2R. The result of this, as can be seen in FIG. 5, is two changes in the current signal I with a different amplitude during each revolution of the antifriction bearing. The changes at the positions w₁, w₃ and w₅ correspond to the case where the rolling body with the resistance value R1 rolls over the defect 10. The changes of the current signal I with the positions w₂, w₄ and w₆ correspond to the case where the rolling body with the resistance value R6 rolls over the defect 10.

An evaluation of the directly electrically detectable characteristic variable, that is to say of the current signal I, in the frequency domain is also advantageous. To this end, the detected reference variable is transformed from the time domain into the frequency domain, for example by means of a Fourier transform. By way of example, FIG. 6 shows an illustration of the output signal A which is produced in the frequency domain. If the same example as FIG. 5 is assumed, two characteristic frequency proportions can be seen at the frequencies f₁ and f₂.

FIG. 7 shows a comparable arrangement as FIG. 4. In contrast to FIG. 4, a spherical rolling body 4 is shown in the embodiment according to FIG. 7, which rolling body 4 has been produced in a sintering process using pressure sensitive particles which are shown as black dots. The zones of the rolling body 4 which are shown in white are metal particles, a binding agent being admixed additionally. The rolling body 4 can be produced, for example, according to the method described in the introduction. As a result, as it were, the entire rolling body 4 becomes pressure sensitive, in such a way that the overall electric resistance of the rolling body 4 changes as a function of a force which is exerted on the rolling body 4. The piezoresistive materials which are mentioned in the introduction, that is to say doped or undoped hydrocarbon or pure carbon, can be used as pressure sensitive material. For the sake of clarity, the size of the individual particles is shown on a considerably larger scale than in reality in FIG. 7.

In the following text, those aspects of the invention will be addressed which have already been addressed above and which result from a slip which always occurs in practice in antifriction bearings between the rolling bodies and the inner and/or the outer bearing ring. In this context, reference is made first of all to FIGS. 8 and 9. In antifriction bearings, the rolling bodies are typically dimensioned with a slight undersize with regard to the spacing between the inner and the outer bearing ring, as shown in principle in FIG. 8. Here, for the sake of clarity, the undersize is shown on a considerably larger scale than in reality. The undersize allows the rolling bodies a certain thermal expansion, without them jamming. However, the undersize also has the result that a certain slip occurs.

A first type of slip occurs when the antifriction bearing rotates in an unloaded state. In this case, no force or only a little force is exerted on the rolling bodies. This leads to the rolling bodies at least partially remaining at a standstill and not rolling along despite the rotating inner or outer bearing ring. If a loading is then exerted on the antifriction bearing, an abrupt acceleration of the rolling bodies takes place, in a similar manner to the wheels of a landing airplane. This leads over time to wear of the rolling bodies and/or the inner or the outer bearing ring and therefore to defects on the antifriction bearing. According to FIG. 8, it is assumed that the inner bearing ring 2 rotates, but at least some rolling bodies 4 are at a standstill.

A second type of slip is produced when the antifriction bearing is loaded in one direction. This is shown by way of example in FIG. 9, in which the inner bearing ring 2 which is rotating as in FIG. 8 is shown somewhat eccentrically with regard to the outer bearing ring 3. The eccentric position of the inner bearing ring is produced by a loading on the inner bearing ring 2 which acts in the direction of the arrow 91, for example by a rotating shaft which is guided by the inner bearing ring 2. This single sided loading leads to only those rolling bodies which are presently carrying a loading performing a rolling movement. This is shown in FIG. 9 using the lower three rolling bodies 4 which are labeled with a round arrow. The remaining five rolling bodies which are labeled with an “x” are outside the loading region. Said rolling bodies which are situated outside the loading region are merely pushed along during the rotation of the inner bearing ring 2, without rolling themselves. As can be seen, the rolling bodies 4 are regularly accelerated to roll along in a loading case of this type, in order subsequently, when they leave the loading zone, to come to a standstill again and to be pushed further. In FIG. 9, the arrow 90 shows at what point the rolling bodies 4 enter the loading zone and therefore transfer into the rotational movement. As a result of the regular starting and coming to a standstill of the rolling bodies, increased wear is produced which shortens the service life of the antifriction bearing.

Both states of imminent wear as a result of an increase in the loading of the antifriction bearing 1, as described using FIGS. 8 and 9, can be determined by way of an antifriction bearing with the pressure sensitive rolling bodies 4, and corresponding countermeasures can be made.

As a result of an increase in the loading of the antifriction bearing, the resistance of the antifriction bearing which can be detected by the monitoring device 12 changes on account of two effects. First of all, the resistance changes on account of the pressure sensitivity of the individual rolling bodies, to be precise approximately inversely proportionally to the force which occurs. In addition, the electric contact between the rolling bodies and the inner and/or the outer bearing ring is changed by a force which is exerted on the antifriction bearing on one side. As a result of increasing force, the contact is improved and the transfer resistance is reduced. In addition, a type of parallel connection effect of the resistances of the individual rolling bodies is produced, as can be seen using FIG. 9, for example. There, the three lower, rotating rolling bodies are connected in parallel practically free from transfer resistances, while the remaining rolling bodies have greater transfer resistances on account of their greater spacing from the bearing rings. As the load on the antifriction bearing increases, the resistance reduction also increases as a result of the parallel connection of the rolling bodies.

In a qualitative illustration, FIG. 10 shows a typical profile of the resistance R which can be measured by the monitoring device 12, as a function of the force F which is exerted on the antifriction bearing in the direction of the arrow 91. A type of step curve is characteristic, the individual curve parts extending hyperbolically. The hyperbolic profile corresponds to the reciprocity between the resistance R and the force F. The sudden changes in the resistance R which additionally occur at the points 100, 101, 102 and 103 result from the fact that an additional rolling body is added for the parallel connection of other rolling bodies, because said rolling body is pressed practically without resistance between the inner and the outer bearing ring as a result of the rise in the force F.

FIG. 11 shows an embodiment of the antifriction bearing 1, in which the outer bearing ring 3 has two electric contact faces 110, 111 which extend in each case by virtually 180° over the circumference of the outer bearing ring. The electric contact faces 110, 111 are insulated with respect to one another and are arranged in the region of the rolling surface of the rolling bodies 4, in such a way that the rolling bodies 4 roll over the electric contact faces 110, 111. The electric monitoring device 7, 8, 12 is connected via in each case one electric line to each of the electric contact faces 110, 111. It is to be assumed that the inner bearing ring 2 rotates and the outer bearing ring 3 is stationary. As a result, a measurement of the electric resistance of the antifriction bearing 1 can take place without a connection to the rotating inner bearing ring 2. No rubbing contacts are therefore required.

More electric contact faces than the two contact faces shown in FIG. 11 can also be provided. In particular, the arrangement of a multiplicity of small electric contact faces is advantageous, as shown, for example, using FIGS. 12 and 13. According to FIG. 12, a multiplicity of electric contact faces 120 to 124 are provided which are arranged, for example, in the rolling surface 135 of the outer bearing ring 3. Each contact face 120 to 124 is connected via an electric connecting line 125 to 129 to the monitoring device 12. For example, every second electric connecting line can be connected to the voltage source 7 and the remaining electric connecting lines are connected to respectively individual measuring resistances, as is shown in Figure by way of example with only two measuring resistances 140, 141. The voltages which drop at the measuring resistances 140, 141 can then be detected by the monitoring device 12, for example via a multiplicity of analog/digital converter inputs or an analog multiplexer. In this way, the points of increased loading over the circumference of the antifriction bearing can be defined.

FIG. 13 shows a comparable arrangement of electric contact faces to FIG. 12, the electric contact faces reaching only approximately as far as the center of the rolling surface 135 of the rolling bodies and being separated in between. This results in two rows of contact faces, namely a left hand row 130 and a right hand row 131. Each individual contact face is connected via a dedicated electric connecting line to the monitoring device 12, for example in the same way as described above for the embodiment according to FIG. 12. The multiplicity of electric connecting lines are shown in FIG. 13 in the form of a left hand row 132 and a right hand row 133 of connecting lines. By way of the embodiment according to FIG. 13, an extended localization of loading minima and loading maxima with regard to the antifriction bearing is possible, to be precise not only with regard to the circumference, but also with regard to the position in the axial direction.

The embodiment of the antifriction bearing according to FIG. 13 permits, in particular, defining of the diverse possible forces and moments which act on the antifriction bearing 1 and are shown in FIG. 15. FIG. 15 shows the antifriction bearing 1 with a rotating shaft 150 which passes through the inner bearing ring 2. As a result of the monitoring device 12, the local pressure distribution of the rolling bodies along the bearing ring can be used, in order firstly to define the axial force Fₐₓ, that is to say the force which acts in the longitudinal direction of the shaft 140. In addition, the radially acting force F_{rad} can be defined, that is to say the force which acts perpendicularly with respect to the axial force Fₐₓ. In addition, defining of the bending moment M and of the direction of the bending moment is possible.

FIG. 16 shows a wind power plant, in which an antifriction bearing according to the invention with pressure sensitive rolling bodies and a monitoring device 12 are provided. The wind power plant serves to generate electric energy by utilization of wind power. To this end, the wind power plant has the components which are known in plants of this type, such as an electric generator 161 and a wind generator 164 which is connected to a drive shaft 162 of the electric generator 161. The electric generator 161 is accommodated, for example, in a machine housing of the wind power plant. The electric generator 161 can be rotated, for example, together with the machine housing via a rotary drive, in order to perform an adaptation to changing wind directions. The rotary drive has an electric motor 165 and a drive shaft 166 which is connected to the electric generator 161 and the machine housing. Furthermore, a control device 160 of the wind power plant is provided, which control device 160 serves to control the electric energy generation and the current feeding into the power grid and to control the rotary drive 165, 166. The control device 160 ensures, for example, tracking of the machine housing in the case of a changing wind direction by actuation of the electric motor 165. Moreover, the control device 160 ensures an output of electric power to the power grid, which output is adapted to the respective requirement.

The drive shaft 162 of the electric generator 160 is mounted via a bearing arrangement 163. The bearing arrangement 163 has an antifriction bearing 1 of the above-described type with pressure sensitive rolling bodies and the components described, for example, using FIG. 4, such as the voltage source 7 and the current sensor 8. The bearing arrangement 163 is connected via electric lines to a monitoring device 12 of the above-described type. The monitoring device 12 uses the electric characteristic variable detected by the antifriction bearing 1 to define slip states and states of increased loading or wear of the antifriction bearing and to generate an output signal which characterizes states of this type. Said output signal is output by the monitoring device 12 to the control device 160. The control device 160 is set up, for example by corresponding programming, for receiving the control signal and for reducing or for avoiding the loading or wear of the antifriction bearing in the case of slip states and if increased loading or wear of the antifriction bearing is determined. For example, in order to reduce unfavorable loadings of the antifriction bearing, the control device 160 can rotate the machine housing by way of the electric motor 165 to such an extent that undesired loading is eliminated. Here, the control device 160 continuously receives the output signal of the monitoring device 12 and can determine from this if a state of reduced loading of the antifriction bearing is reached. A further option consists of the fact that, for example on account of load changes on the antifriction bearing which result from wind strength changes, the control device 160 adapts the energy discharge into the power grid accordingly, in order to reduce loading of the antifriction bearing as a result.

In the above-described exemplary embodiments, an antifriction bearing in the form of a radial bearing has been assumed. A radial bearing is configured predominantly for absorbing radial forces. The above-described possible applications and advantages also apply to antifriction bearings which are configured, for example, as axial bearings or as a mixed form of radial bearing and axial bearing. FIG. 17 shows, by way of example, an axial bearing 1 which is designed for absorbing axial forces. Here, the bearing ring which is depicted at the bottom of FIG. 17 is provided as first bearing ring 2, and the bearing ring which is depicted at the top is provided as second bearing ring 3. Therefore, with reference to the preceding comments, the lower bearing ring 2 corresponds to the inner bearing ring of a radial bearing. The upper bearing ring 3 corresponds to the outer bearing ring. As can be seen, a multiplicity of rolling bodies 4 are arranged between the upper bearing ring 3 and the lower bearing ring 2 in the axial bearing 1 according to FIG. 17. In addition, a rolling body cage 170 is shown, by way of which the rolling bodies 4 are held at a predefined spacing from one another.

1. Rotatable antifriction bearing (1) having a first bearing ring (2), a second bearing ring (3) which can be rotated with respect to the first bearing ring (2), and a plurality of rolling bodies (4) which are arranged between the first and the second bearing ring (2, 3), wherein at least one rolling body (4) is configured as an electric sensor in such a way that the rolling body (4) is set up for changing a directly electrically detectable characteristic variable as a function of a force which is exerted on said rolling body (4).

2. Antifriction bearing according to claim 1, wherein the rolling body (4) which is configured as an electric sensor is configured as a piezoelectric sensor or a piezoresistive sensor.

3. Antifriction bearing according to claim 1, wherein the rolling body (4) which is configured as an electric sensor is produced from a piezoresistive material or has a coating (6) which is made from a piezoresistive material and is applied to an inner core (5) of the rolling body.

4. Antifriction bearing according to claim 3, wherein the coating (6) made from the piezoresistive material is produced with doped or undoped hydrocarbon or pure carbon.

5. Antifriction bearing according to claim 3 wherein at least one wear protection layer (11) is applied to the rolling body (4) or the piezoresistive coating (6).

6. Antifriction bearing according to claim 5, wherein the wear protection layer (11) has a plurality of conductive zones which are insulated with respect to one another or are at least highly resistive in comparison with the rolling bodies (4).

7. Antifriction bearing according to claim 1, wherein the second bearing ring (3) is insulated with respect to the first bearing ring (2) or is at least highly resistive in comparison with the rolling bodies (4).

8. Antifriction bearing according to claim 1, wherein a plurality of rolling bodies (4) are configured as electric sensors and the spacings of which from one another are unequal in the circumferential direction of the antifriction bearing (1).

9. Antifriction bearing according to claim 1, wherein a plurality or all of the rolling bodies (4) are configured as electric sensors, at least one part quantity of said rolling bodies (4) having a different electric characteristic than the remaining rolling bodies (4) which are configured as electric sensors.

10. Antifriction bearing according to claim 8, wherein rolling bodies (4) with the same electric characteristic are arranged such that they are distributed asymmetrically over the circumference of the antifriction bearing (1).

11. Antifriction bearing according to claim 1, wherein the first bearing ring (2) and/or the second bearing ring (3) have/has at least one inhomogeneity, in particular at least one defined conductivity modification, with regard to the directly electrically detectable characteristic variable in the region of the rolling surface of the rolling bodies (4).

12. Antifriction bearing according to claim 1, wherein the antifriction bearing (1) has a rolling body cage which is provided for spacing the rolling bodies (4) from one another, the rolling body cage being produced from an insulating material or being coated with the latter.

13. Antifriction bearing (1) according to claim 1, wherein the rolling body (4) is produced from or using pressure sensitive particles which themselves change a directly electrically detectable characteristic variable as a function of a force which is exerted on them.

14. Antifriction bearing (1) according to claim 13, wherein the rolling body (4) is produced from a mixture of the pressure sensitive particles and of metal particles.

15. Antifriction bearing (1) according to claim 13, wherein the rolling body (4) additionally has a binding agent.

16. Antifriction bearing (1) according to claim 1, wherein the rolling body (4) is produced by a sintering process.

17. Antifriction bearing (1) according to claim 1, wherein the rolling body (4) is produced from or using metal particles which have a coating which is applied to an inner metal core and is made from a piezoelectric or piezoresistive material.

18. Antifriction bearing (1) according to claim 1, wherein in the region of the rolling surface (135) of the rolling bodies (4), the first bearing ring (2) and/or the second bearing ring (3) have/has at least two electric contact faces (110, 111, 120, 121, 122, 123, 124) which are arranged distributed over the circumference of the rolling surface (135), are insulated with respect to one another and are made from electrically conductive material for making contact with the rolling bodies (4).

19. Antifriction bearing (1) according to claim 1, wherein in the region of the rolling surface (135) of the rolling bodies (4), the first bearing ring (2) and/or the second bearing ring (3) have/has electric contact faces (130, 131) which are arranged distributed in the direction of the rotational axis (150) of the antifriction bearing (1), are insulated with respect to one another and are made from electrically conductive material for making contact with the rolling bodies (4).

20. Rolling body for an antifriction bearing (1) according to claim 1.

21. Device having an antifriction bearing (1) according to claim 1 and having an electric monitoring device (7, 8, 12), the monitoring device (7, 8, 12) being connected electrically to the antifriction bearing (1) and being set up for detecting the directly electrically detectable characteristic variable of the rolling bodies (4) or of the antifriction bearing (1).

22. Device according to claim 21, wherein the monitoring device (7, 8, 12) is set up for evaluating the time profile of the detected electric characteristic variable for irregularities and, if an irregularity which exceeds a predefined dimension is determined, for outputting a warning signal.

23. Device according to claim 21, wherein the monitoring device (7, 8, 12) is connected electrically to the second bearing ring (3) and the first bearing ring (2) of the antifriction bearing (1) and is set up for detecting an electric characteristic variable between the second bearing ring (3) and the first bearing ring (2).

24. Device according to claim 21, wherein the monitoring device (7, 8, 12) is set up for determining slip states and/or states of increased loading or wear of the antifriction bearing (1) from the detected electric characteristic variable and for generating an output signal which characterizes states of this type.

25. Device according to claim 24, wherein the monitoring device is set up for generating a control signal if a slip state is determined and/or if increased loading or wear of the antifriction bearing (1) is determined, a control device (160) being provided which is set up for receiving the control signal and, if a slip state is determined and/or increased loading or wear of the antifriction bearing (1) is determined, for reducing or for avoiding the loading or wear of the antifriction bearing (1), which loading or wear is current or is imminent as a result of the slip state.

26. Device according to claim 25, wherein the control device (160) is set up, in order to avoid or reduce the increased loading or wear, for at least temporarily reducing the rotational speed which acts on the antifriction bearing (1) and/or for increasing said rotational speed only slowly and/or for increasing a detected loading of the antifriction bearing (1) only slowly.

27. Device according to claim 21, wherein the monitoring device (7, 8, 12) is set up for using the detected electric characteristic variable to locally define an actual loading maximum and/or loading minimum of the antifriction bearing (1) along the rolling surface (135) of the rolling bodies (4) over the circumference of the antifriction bearing (1) and/or in the direction of the rotational axis (150) of the antifriction bearing (4).

28. Device according to claim 21, wherein the monitoring device (7, 8, 12) is set up for using the detected electric characteristic variable to define a radial force (F_{rad}), an axial force (Fₐₓ) and/or a bending moment (M) which acts on the antifriction bearing (1) and/or the direction of action of the bending moment (M).

29. Device having an antifriction bearing (1) according to claim 1, the monitoring device (7, 8, 12) being connected electrically only to the second bearing ring (3) or only to the first bearing ring (2) of the antifriction bearing (1), and being set up for detecting an electric characteristic variable between at least two contact faces (110, 111, 120, 121, 122, 123, 124, 130, 131) of the second bearing ring (3) or of the first bearing ring (2), which contact faces (110, 111, 120, 121, 122, 123, 124, 130, 131) are insulated electrically with respect to one another.

30. Device according to claim 29, wherein the bearing ring (2, 3), to which the monitoring device (7, 8, 12) is connected electrically, is configured as a static bearing ring which does not rotate during the operation of the antifriction bearing (1).
